(19) United States
(12) Patent Application Publication
(10) Pub. No.: US 2006/0154380 A1
(43) Pub. Date: Jul. 13, 2006

(54) Synthesis of ordered arrays from gold clusters

(76) Inventors: Shunji Egusa, Chicago, IL (US); Rongchao Jin, Evanston, IL (US); Norbert F. Scherer, Winnetka, IL (US)

Correspondence Address: BRINKS HOFER GILSON & LIONE, P.O. BOX 10395, CHICAGO, IL, 60610, US

(21) Appl. No.: 11/159,778

(22) Filed: Jun. 23, 2005

Related U.S. Application Data
(60) Provisional application No. 60/582,480, filed on Jun. 23, 2004.

(51) Int. Cl. H01L 21/00

(52) U.S. Cl. 438/1; 977/852

(57) ABSTRACT

A nanocluster includes 1 to 7 metal atoms and has at least one ligand, which is associated with at least one of the metal atoms. A method of making a nanocluster consists of combining a nanoparticle, a ligand and a high boiling point solvent to provide a mixture and heating the mixture at a temperature of at least about 125° C. to form a nanocluster with 1 to 7 metal atoms. An ordered array of nanostructures includes a substrate and a plurality of nanostructures on the substrate, where the nanostructures are made by forming a solution of nanoclusters, depositing the solution on a substrate, and heating the substrate.

### RELATED APPLICATIONS

This application claims priority to U.S. provisional application Ser. No. 60/582,480 filed Jun. 23, 2004. The disclosure of the priority application is incorporated by reference herein in its entirety.

### FEDERALLY SPONSORED RESEARCH OR DEVELOPMENT

The present invention described herein was supported at least in part by NSF MRSEC (DMR-0213745) and NSF (#CHE0317009). The government has certain rights in the invention.

### BACKGROUND

Metal and semiconductor nanoclusters have become an important class of materials that are having a major impact in materials science, chemistry, physics, as well as the biological and environmental sciences. Early research on nanoclusters was primarily focused on gas-phase beam experiments, including spectroscopic studies of their structural and electronic properties. These gas-phase clusters are typically short-lived and are difficult to chemically functionalize for applications such as catalysis or electron microscopy contrast enhancement of biological samples. Therefore, since the 1980's, a great deal of research has focused on solution phase chemical synthesis of nanoclusters. A number of synthetic methods have been reported for the preparation of high quality, relatively monodisperse, and ligand stabilized nanoclusters. For example, Au₇₅, Au₅₅, Au₂₈, Au₁₁, and Au₈, as well as different sized Ag nanoclusters, have been synthesized, and the catalytic and photoluminescence properties of these species were extensively studied. These synthetic strategies not only lead to nanoclusters with good stability, but also allowed tailoring of their physical and chemical properties.

Nanoclusters have been employed to form certain types of nanostructures, which may find applications in a number of fields, including optical frequency communication, microelectronics, computation technology, biological and medical labeling, and chemical catalysis. In some cases, nanostructures can be assembled into ordered arrays, where these ordered arrays are assembled on a surface or substrate. Ideally, an ordered array will be composed of nanostructures of substantially uniform size, which are also arranged on the substrate in a uniform and/or repeating geometric pattern. Furthermore, it is desirable to be able to generate ordered arrays where the shape of the component nanostructures can be controlled, since the shape will affect the physical properties and attributes of the ordered array. These ordered arrays may be of particular significance and interest because, among other things, they can manipulate light at nanometer length scales. New synthetic strategies may provide nanoclusters with enhanced stability and/or which have the ability to self-organize or assemble into ordered arrays of nanostructures.

### BRIEF SUMMARY

In one aspect, there is a nanocluster, comprising from 1 to 7 metal atoms and at least one ligand, where the at least one ligand is associated with at least one of the metal atoms.

In another aspect, there is a method of making a nanocluster, comprising combining a nanoparticle, a ligand and a high boiling point solvent to provide a mixture and heating the mixture at a temperature of at least about 125° C. to form a nanocluster comprising from 1 to 7 metal atoms.

In yet another aspect, there is a nanocluster comprising from 1 to 7 metal atoms, where the nanocluster is formed by combining a nanoparticle, a ligand, and a high boiling point solvent to provide a mixture and heating the mixture at a temperature of at least 125° C.

In yet another aspect, there is an ordered array comprising a substrate and a plurality of nanostructures comprising gold on the substrate, where the nanostructures are cubes.

In yet another aspect, there is a method of making an ordered array of nanostructures, comprising: forming a solution of nanoclusters in a high boiling solvent; depositing the solution on a substrate; and heating the substrate.

In yet another aspect, there is an ordered array of nanostructures comprising a substrate and a plurality of nanostructures on the substrate, where the nanostructures are made by forming a solution of nanoclusters, depositing the solution on a substrate, and heating the substrate.

### BRIEF DESCRIPTION OF THE DRAWINGS

FIG. 1A is a MALDI spectrum of Au nanoclusters.

FIG. 1B is an ESI-MS spectrum of Au nanoclusters with dodecanethiol ligand performed at an inonization voltage of 70 V.

FIG. 2 shows a series of UV-Vis spectra where the solid line is an optical absorption spectrum of Au nanoclusters and the dashed line is a photoluminescence spectrum of Au nanoclusters.

FIG. 3 shows a series of time dependent UV-Vis spectra of the conversion of Au nanoparticles to Au nanoclusters.

FIG. 4 is a TEM of an ordered array of Au spheres, wherein the ordered array of Au spheres was created using dodecanethiol passivated Au nanoclusters.

FIG. 5A is a TEM of an ordered array of Au cubes, wherein the ordered array of Au cubes was created using dodecanethiol passivated Au nanoclusters.

FIG. 5B is a TEM of an ordered array of Au cubes, wherein the ordered array of Au cubes was created using dodecanethiol passivated Au nanoclusters.

FIG. 6 is a TEM of an ordered array of Au wires, wherein the ordered array of Au wires was created using dodecanethiol passivated Au nanoclusters.

FIG. 7 is a graph demonstrating the relationship between the fluid layer thickness and the lattice constant of an ordered array of Au spheres.

FIG. 8 is a TEM of an ordered array of Au spheres, wherein the ordered array of Au spheres was created using nanoclusters with octanethiol ligand.

FIG. 9 is a TEM of an ordered array of Au cubes, wherein the ordered array of Au cubes was created using nanoclusters with octanethiol ligand.

FIG. 10 shows optical absorption spectra (UV-vis) of Ag nanoclusters with dodecanethiol ligand (solid line) and Ag nanoclusters with oleic acid ligand (dashed line).

FIG. 11 shows Emission (fluorescence) spectra of Ag nanoclusters with dodecanethiol ligand (solid line) and Ag nanoclusters with oleic acid ligand (dashed line).

FIG. 12 shows a TEM of an ordered array of Ag spheres, wherein the ordered array of Ag spheres was created using nanoclusters with oleic acid ligand.

FIG. 13 shows emission (fluorescence) spectra of an Au nanocluster solution prepared at 290° C. and an Au nanocluster solution prepared at 270° C.

### DETAILED DESCRIPTION

The present invention includes nanoclusters and methods of forming nanoclusters. The present invention also includes arrays of nanostructures and the use of nanoclusters to form these arrays. A method of forming nanoclusters includes converting a nanoparticle starting material to a nanocluster that is stabilized with at least one ligand. The conversion from the nanoparticle to the nanocluster may be achieved by refluxing the nanoparticles in a high boiling point solvent in the presence of excess ligand. The resulting nanoclusters are extremely stable and may serve as building blocks for the synthesis of ordered arrays of nanostructures. Under the appropriate conditions the nanoclusters can undergo self-organization, on a substrate, to form the ordered arrays. This process can provide ordered arrays where the nanostructures are cubes, wires, or spheres, depending on the temperature at which the nanoclusters are cured on the substrate.

The term “Nanocluster”, as used herein, refers to a substance having from 1 to 7 metal atoms. A nanocluster may also contain other atoms that are not metals, including non-metals such as oxygen, sulfur, nitrogen and carbon, silicon and germanium. A nanocluster may also include at least one ligand associated with at least one of the metal atoms.

As used herein, “metal atom” refers to any atom in groups IIB-VIIIB. In one configuration, the metal atom may be selected from the group consisting of Au, Ag, Fe, Co, Pt, Cu, Ni, Cd, Zn, Mn, Sn, Pb, V, Ti. Preferably, the metal atom is Au or Ag. More preferably, the metal atom is Au.

The metal atoms in the nanocluster may be present in pure form without any other atoms. The metal atoms in the nanocluster may be present as a mixture with other metal atoms, such as a mixture of Au and Ag. The metal atoms may also be present as compounds with atoms that are not metals. Examples of metal compounds include Fe₂O₃, Fe₃O₄, Co₃O₄, CdS, CdSe, CdTe, ZnO, MnO₂, SnO₂, PbS, PbSe, V₂O₅, TiO₂, and SiO₂.

The number of metal atoms in the nanocluster may range from 1 to 7. Preferably, the nanocluster contains from 2 to 7 metal atoms, more preferably from 2 to 6 metal atoms, more preferably still from 2 to 5 metal atoms, more preferably still from 2 to 4 metal atoms. In one example, the number of metal atoms in the nanocluster may vary from 1 to 3. In another example, the nanocluster contains 3 metal atoms.

The term “Ligand”, as used herein, refers to a carbon containing molecule or radical that is associated with, or is capable of being associated with, the nanocluster. “Associated with” as used herein, refers to the attractive interaction between one or more metal atoms in a nanocluster and one or more atoms in a ligand. “Association with” includes, for example, coordination, covalent bonding, ionic interaction, or complexation. Without wishing to be bound by any theory of interpretation, it is believed that the ligand(s) serve to stabilize or passivate the nanocluster, resulting in the observed longevity of the nanocluster species. For example, gold nanoclusters containing a dodecanethiol ligand were monitored by UV-vis spectroscopy and showed no degradation during a two month period.

In one example, the ligand may be represented as X—R, where X is the point of association with the metal. The X group may be O, N, S, or P. The R group is an organic moiety containing, for example, C₁₋₂₀ alkyl, C₂₋₂₀ alkenyl, C₂₋₂₀ alkynyl, C₆₋₁₀ aryl or 3- to 10-membered heteroaryl ring. The R group may be substituted with substituents including, for example Cl, Br, F, ═O, —CN, —OR′, —SR′, —S(O)R′, —S(O)₂R′, —NR′R″, —C(O)R′, —CO₂R′, and —P(O)₂OR′, where R′ and R″ are hydrogen or C₁₋₂₀ alkyl. In one example, X is sulfur and R is C₁₋₂₀ alkyl. Preferably, R is C₁₋₂₀ alkyl; more preferably, X is sulfur and R is dodecyl. In one configuration, where R is C₂₋₂₀ alkenyl that is substituted with X═—C(O)₂R′, where R′ is hydrogen, the ligand may be oleic acid.

In one configuration, the ligand may be derived from a substance having the formula H—X—R. For example, where X is S, the ligand starting material may be H—S—R; where X is N, the ligand starting material may be H₂N—R or HN—R. As used herein, the term ligand refers to both the moiety associated with the nanocluster and to the ligand starting material.

The ligand may be permanently associated with the cluster, or it may be labile. A “labile ligand”, as used herein, refers to a ligand which may be capable of undergoing exchange with a second ligand, where the second ligand possesses a different chemical identity from the ligand. For example, the second ligand may be a substituted alkyl ligand, whereas the labile ligand may have been an unsubstituted alkyl ligand.

In one configuration, the nanoclusters may be prepared as described in Example 1, where the first ligand is 1-dodecanethiol. These nanoclusters may then undergo ligand exchange with a second ligand. For example, 1-dodecanethiol may be exchanged with a phosphine ligand. The synthesis of nanoclusters may occur at a variety of temperatures. For example, Example 1 describes a synthesis of nanoclusters using octyl ether, where the conversion of Au nanoparticles to Au nanoclusters is carried out at ˜300° C. using 1-dodecanethiol as the ligand. It may be possible to exchange the ligand for the second ligand at a lower temperature. This may be especially useful when the second ligand is not stable at the temperatures at which the conversion of nanoparticles to nanoclusters is carried out.

In one configuration, it may be possible to exchange the ligand for the second ligand, where the second ligand is a protein. As used herein, “protein” refers to any of a group of complex organic macromolecules that contain carbon, hydrogen, oxygen, nitrogen, and optionally sulfur and that are composed of one or more chains of amino acids. For example, the second ligand may be a protein in the form of an antibody. In this manner, it may be possible to employ the nanocluster in a variety of biological assays, such as immunoassays. Gold-labeled antibodies and their use in immunoassays is described, for example, in Mattoussi, H., Medintz, I. L., Clapp, A. R., Goldman, E. R., Jaiswal, J. K., Simon, S. M., Mauro, M., JALA 9, 28 (2004). In another configuration, it may be possible to exchange the ligand for the second ligand, where the second ligand is attached to a surface. In this way, nanoclusters can be immobilized on substrates such as a bead, a cuvette, a microtiter plate, or a semiconductor chip.

Nanoclusters may be synthesized by mixing a nanoparticle, a ligand, and a high boiling point solvent to provide a mixture. This mixture is then heated at a temperature of at least about 125° C. to form a solution of nanoclusters. The nanoclusters may be isolated or they may be used in solution. For example, the solution of nanoclusters may be employed in the synthesis of an ordered array of nanostructures.

As used herein “nanoparticle” refers to a substance having more than 7 metal atoms. Nanoparticles may be prepared using a variety of conventional procedures or may be obtained from commercial sources.

In one example, nanoparticles may be synthesized by mixing a metal salt, an ammonium halide, a reductant, a solvent, and a ligand to provide a colloid of nanoparticles that are suspended in the solvent. Next, the nanoparticle may be removed from suspension by way of precipitation and washing. A variety of metal salts may be employed in this or similar syntheses of the metal nanoparticle. Examples of metal salts that may be used in the synthesis of Au nanoparticles include, but are not limited to, AuCl₃, NaAuCl₄, NH₄AuCl₄, HAuCl₄, NH₄Au(CN)₂, and KAuBr₄. Examples of reductants include, but are not limited to, NaBH₄, hydrazinium hydrate, LiBH₄, metallic sodium dispersion in oil, lithium triisoamyl borohydride, lithium triethyl borohydride, LiAlH₄, butyl lithium, or UV light. Examples of ammonium halides include alkyl ammonium halides, aryl ammonium halides, and mixed alkyl/aryl ammonium halides. An assortment of these compounds may be used, including but not limited to didodecyldimethylammonium bromide (DDAB). Examples of solvents include non-protic solvents such as toluene. In one specific example, Au nanoparticles may be synthesized where the metal salt is AuCl₃, the ammonium halide is didodecylammonium bromide, the reductant is NaBH₄, the solvent is toluene, and the ligand is dodecylthiol.

As used herein, “high boiling point solvent” refers to a solvent with a boiling point above 125° C. at 760 mm Hg. The high boiling solvent employed in the synthesis of the nanocluster may include, but is not limited to, didecyl ether, didodecyl ether, phenyl ether, octyl ether, tributylphosphine oxide, trioctylphosphine oxide, or dibutyloctylphosphine oxide. Preferably, the high boiling point solvent is octyl ether. A “high boiling point solvent” also refers to a solvent having a boiling point below 125° C., where the solvent is heated under pressure such that it reaches a temperature above 125° C.

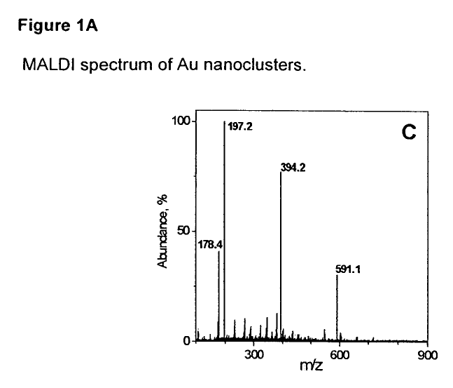

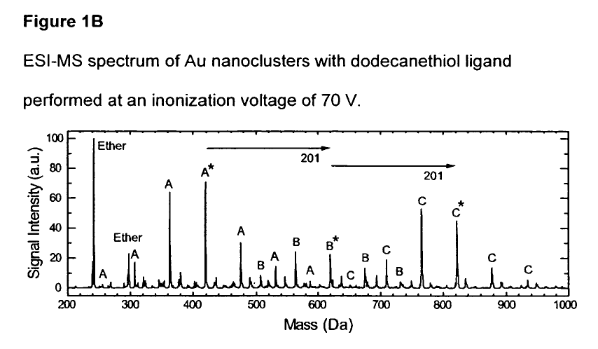

Analysis of the nanoclusters may be performed using a variety of techniques, including matrix-assisted laser desorption/ionization (MALDI) and UV-vis spectroscopy. For example, a gold nanocluster formed using dodecylthiol as the ligand (Example 1, below) was analyzed using MALDI, which provided a spectrum with peaks (m/z) at 197.2, 394.1, and 591.5 (FIG. 1A). The peaks at 197.2, 394.1, and 591.5 of FIG. 1A likely correspond to Au⁺ (monomer), Au₂⁺ (dimer), and Au₃⁺ (trimer) respectively. In addition a gold nanocluster formed using dodecylthiol as the ligand (Example 1, below) was also analyzed using electrospray ionisation mass spectrometry (ESI-MS) (FIG. 1B). FIG. 1B provides an ESI-MS characterization of the atomic Au cluster (temperature 290° C., molar ratio 1:100). The peaks are believe to correspond to three main species, A: Au[C₁₂H₂₅S]⁺; B: Au[C₁₂H₂₅S]₂⁺; C: Au[C₁₂H₂₅S]₃⁺, plus Na and CH₂ fragment adducts/deducts, with [CH₂]₄ being lost preferentially.

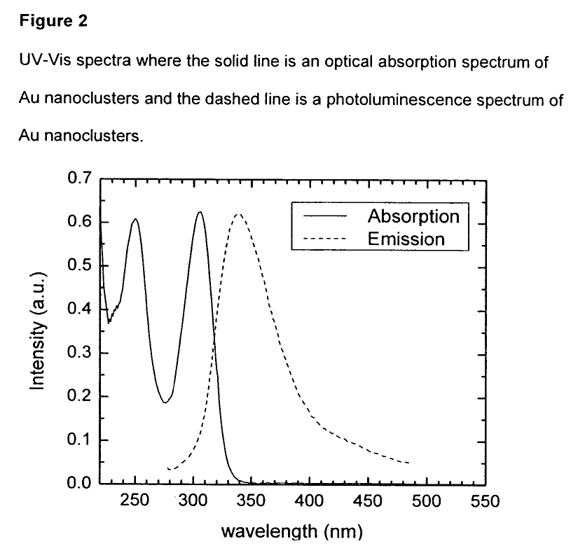

Without wishing to be bound by any theory of interpretation, it is believed that the clusters prepared in this example are likely molecular Au trimers, i.e., Au₃(SC₁₂H₂₅)₃. The monomers and dimers observed in the mass spectrum may result from laser-induced dissociation of the parent trimer. Analysis of the Au nanocluster using UV-vis provided an optical absorption spectrum showing optical transitions at 308 nm and 250 nm (FIG. 2, solid line). These transitions are consistent with Au₃(SC₁₂H₂₅)₃. Analysis with UV-vis also provided a photoluminescence spectrum FIG. 2 (dashed line), which also shows a strong fluorescence emission at 340 nm.

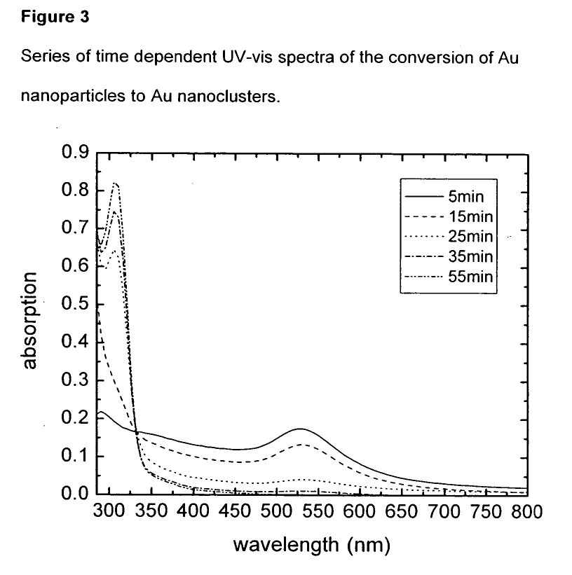

The conversion of nanoparticles to nanoclusters can be monitored. For example, the change in optical properties of the colloid can be measured as the conversion progresses. The results of a time dependent UV-vis analysis of a conversion from nanoparticles to nanoclusters are shown in FIG. 3. The spectra provided in FIG. 3 correspond to samples which were removed at different times as the mixture of gold colloid, dodecylthiol and octyl ether was heating. The conversion appears to have been complete after approximately 50 minutes of heating, since TEM showed no remaining nanoparticles. The Au nanoparticulate starting material used in this example was visible on TEM, while the Au nanoclusters were not. This conversion to nanoclusters is in contrast to nanoparticle treatments that do not use a high boiling solvent. For example, the solid line in FIG. 3 represents the product provided by heating a particle in toluene in the presence of a ligand (Prasad, B. L. V.; Stoeva, S. I.; Sorensen, C. M.; Klabunde, K. J. Langmuir 2002, 18, 7515), while the dashed line, corresponding to 55 minutes, represents the nanocluster of Example 1.

These nanoclusters could have numerous applications. For instance, the nanoclusters could serve as fluorescent labels in a variety of biological assays. See U.S. Pat. No. 6,630,307. Fluorescence is the emission of light resulting from the adsorption of radiation at one wavelength (excitation) followed by nearly immediate reradiation usually at a different wavelength (emission). Organic fluorescent dyes are typically used in this context. However, there are chemical and physical limitations to the use of such dyes. See id. It may be possible to overcome these limitations using nanoclusters. Furthermore, the nanostructure array could be embedded in a solid, for example by polymerization of a fluid monomer. Embedding the nanoarrays within a solid can significantly modify the optical and electrical responses of the nanoarrays. The nanocluster could also be embedded in a solid, for example by polymerization of a fluid monomer. The embedded nanoclusters may find application in extending the spectral response of UV-vis detectors, such as CCD detectors. Currently, CCD UV-vis detectors have a UV cut-off at ˜300 nm and thus will not detect shorter wavelengths. The gold nanoclusters can convert light with wavelengths shorter than 300 nm into 340 nm, which can be detected by CCD detectors. It may also be possible to enhance the spectral range of the nanoclusters as fluorescent dyes via ligand exchange. In addition, the nanoclusters may be used as wavelength standards, particularly in the UV spectral range. Also, the gold nanoclusters efficiently absorb UV-C (250-280 nm) from artificial radiation sources and absorb UV-B (280-320 nm), which is responsible for sunburns. Furthermore, the gold nanoclusters may also find applications in radiotherapy, since Hainfield et al. have shown that gold particles having a diameter of 1.9 nm can be used to enhance radiotherapy in mice. See Hainfeld, James F., et al. Phys. Med. Biol. 49, N309-N315 (2004).

Nanoclusters may be used to form an ordered array of nanostructures. As used herein, an “ordered array of nanostructures” refers to a plurality of nanostructures, where the nanostructures are arranged on a substrate and are of generally uniform geometry and size. As used herein, “nanostructure” refers to a structure or pattern containing features which are 500 nanometers (nm) or smaller.

The substrate may be any surface onto which the solution of nanoclusters can be applied, for formation of the ordered array of nanostructures. The substrate can be flexible or rigid, and examples of substrate materials include polymers, ceramics (including glass), metals, semiconductors, and carbon. In one example, TEM grids may be employed as the substrate. Possible TEM grids include, but are not limited to carbon, silicon oxide, and silicon nitride. In one configuration, the substrate may be planar.

Preferably the nanostructures within an array of nanostructures have a uniform size. The uniformity of the size of the nanostructures may be expressed in terms of variability, which is calculated by dividing the standard deviation of the sizes of the nanostructures by the average size of the nanostructures, and multiplying by 100%. Preferably, the variability of the size of the nanostructures is less than 20%. More preferably, the variability of the size of the nanostructures is less than 10%, and more preferably is less than 7%. The possible geometries of the nanostructures include, but are not limited to spheres, cubes and wires.

As used herein, “sphere” refers to a nanostructure where the geometry is that of a sphere having a diameter less than 500 nm. The size of the spheres may range from about 1 nm to about 20 nm; preferably from about 3 nm to about 20 nm.

As used herein, “cube” refers to a nanostructure where the geometry is that of a cube having six distinct sides, where the largest distance from one side to another is less than 500 nm. The size of the cubes may range from about 1 nm to about 20 nm; preferably from about 5 nm to about 20 nm.

As used herein, “wire” refers to a nanostructure, where the geometry is that of a curved or linear wire having a width of less than 10 nm. Preferably the width of the wires in an ordered array of wires is from about 1 nm to about 10 nm, more preferably from about 1 nm to about 5 nm.

Nanostructures may be arranged on the substrate, such that the distance between each nanostructure and its nearest neighbor is generally uniform. One method of representing the uniformity is via a lattice constant. As used herein, “lattice constant” refers to the inter-nanostructure distance between the centers of two neighboring nanostructures. Where the nanostructures are cubes, the lattice constant of the ordered array may range from about 1 nm to about 20 nm. Preferably the lattice constant of the ordered array of cubes is from about 5 nm to about 10 nm. The lattice constant for the ordered array of spheres may range from about 1 nm to about 20 nm. Preferably the lattice constant of the ordered array of spheres is about 5 nm to about 10 nm. The ordered arrays of nanostructures, as described herein, may be “two-dimensional” or “three dimensional.” As used herein, “two-dimensional” refers to an ordered array wherein the individual nanostructures typically comprise one layer of nanostructures. As used herein, “three-dimensional” refers to an ordered array wherein the individual nanostructures typically comprise multiple layers of nanostructures.

An ordered array of nanostructures may be synthesized by forming the solution of nanoclusters in a high boiling solvent and then depositing the solution on a substrate. The solution of nanoclusters may be optionally diluted with a second solvent, to form a diluted-solution of nanoclusters. The second solvent may include toluene, benzene, hexane, cyclohexane, acetone, methanol, ethanol, and acetonitrile. The substrate and the deposited solution are then heated to provide an ordered array of nanostructures. In one configuration, the heating may be performed by placing the substrate on a hotplate. The ordered array of nanostructures may result from the self-assembly or organization of the nanoclusters.

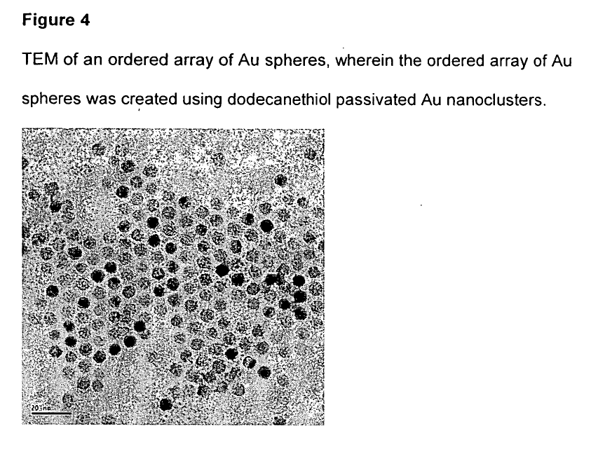

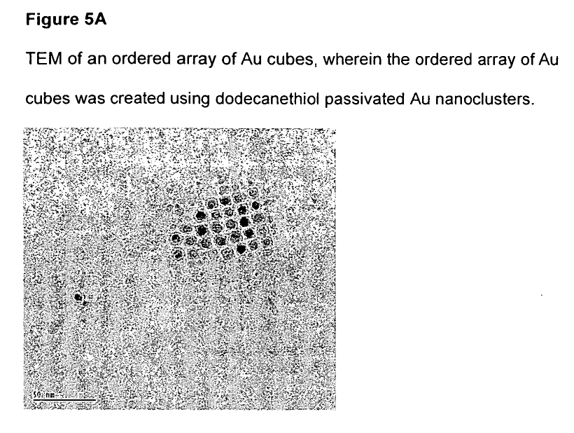

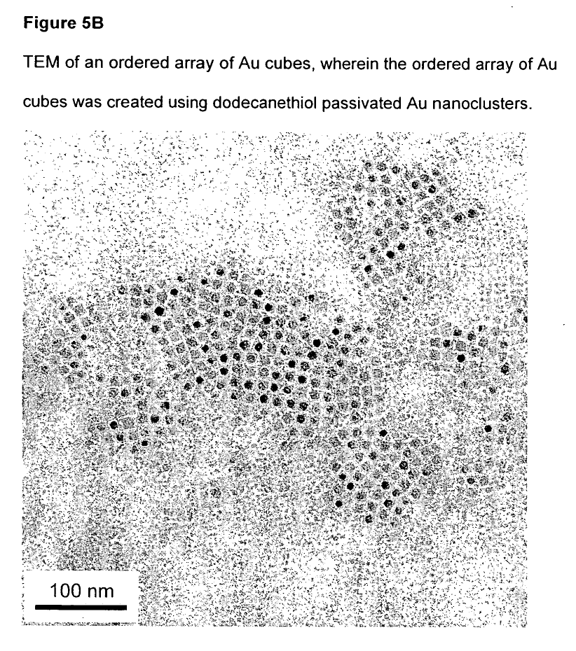

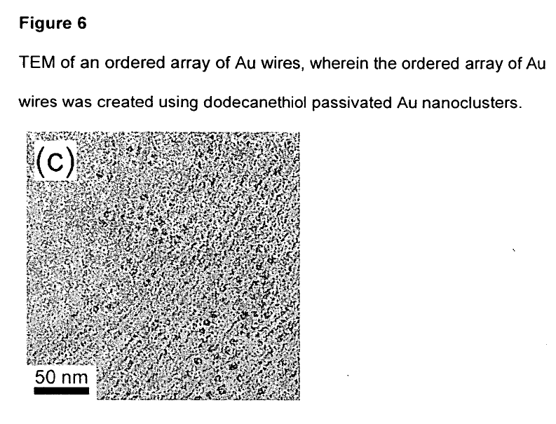

The temperature at which the heating is performed may affect the geometry of the resulting nanostructures. In one configuration, the geometry of the nanostructures of the ordered array may be controlled by the temperature at which the substrate is heated. For example, when a 1:2 diluted-solution of Au nanoclusters, as prepared in Example 1, was heated at 95° C. on a carbon TEM grid, an ordered array of spheres was provided (FIG. 4). When the 1:2 diluted-solution of Au nanoclusters, as prepared in Example 1, was heated at 105° C. on a carbon TEM grid, an ordered array of cubes was provided (FIG. 5A and FIG. 5B). When the 1:2 diluted-solution of Au nanoclusters, as prepared in Example 1, was heated at 100° C. on a carbon TEM grid, an ordered array of wires was provided (FIG. 6).

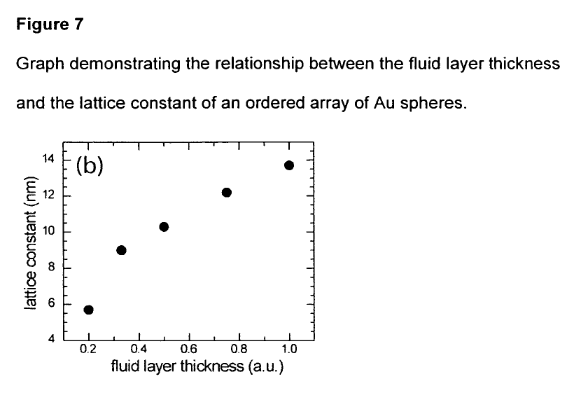

The lattice constant of the ordered array of nanostructures may be affected by the fluid layer thickness. In fact, changing the fluid layer thickness may provide a method for controlling the lattice constant of the ordered array of nanostructures. The fluid layer thickness may be controlled by the dilution ratio of the original solution by the second solvent, for example toluene. The fluid layer thickness also may be controlled by changing the amount of deposited sample, without the toluene dilution. For example, FIG. 7 reveals that the lattice constant for the ordered array of Au spheres increases with increases in the fluid layer thickness.

Without wishing to be bound by any theory of interpretation, it is believed that a plausible mechanism for the formation of the organized arrays is Bénard convection, or the self-organization of a thin fluid layer. There are three possible temporally stable Bénard convection patterns: hexagonal and square convection cells, and convective rolls. Bénard-Marangoni convection is a surface tension driven instability occurring when a vertical temperature gradient ΔT is imposed uniformly across the bottom and the top of a thin layer of fluid. This instability is described by the dimensionless Marangoni number M:

$$M = \frac{\partial S}{\partial T} \frac{1}{{ρ}_{0} κ v} Δ Td ,$$

(S: surface tension; ρ₀: average mass density of the fluid; κ: thermal diffusivity; v: kinematic viscosity; d: fluid thickness). Usually, the Marangoni number has to exceed the critical value (M_{C}˜80) for a convection mode to be set. The estimate of the instability parameters in the nanocluster solution, assuming a classical fluid, is not believed to be high enough to cause super-critical convections. However, it is noted that sub-critical convections may occur when the spatial distribution of surface tension is non-uniform and introduces seed fluctuations in the system. The TEM grid is typically heated at the bottom surface while evaporation of the solvent cools the top surface; hence a temperature gradient is maintained. The evaporation of the solvent from the top surface, the meniscus of the fluid, within a TEM grid window etc. may induce sub-critical Marangoni instability of non-Boussinesq fluid. The ratio of the lattice constants of the square- and hexagonal-ordered arrays of nanostructures, described below in Examples 3 and 4 respectively, is α_{sq}/αₕₑₓ=1.26±0.03. This is consistent with the theoretical ratio of the lattice constants of the Bénard convection cells, which is α_{sq}/αₕₑₓ=1.29. The observed linear dependence of the lattice constant on the fluid layer thickness is also consistent with this theory. When the convection cell size is smaller than ˜10 nm, the dependence deviates from linearity, possibly because the molecular behavior, rather than the continuum behavior, of the fluid becomes more prominent.

Without wishing to be bound by any theory of interpretation, it is believed that the formation of an ordered array of nanostructures may occur in three distinct stages. Stage I. Formation of Bénard convection cell lattice: Nanostructures are absent without baking. With baking, a vertical temperature gradient may be established in the thin layer of solvent containing the nanoclusters, and the solvent may self-organize to form the convection cell lattice. The nanoclusters may move along with the convection flow. The definition of the nucleation sites may occur while the direction of the flow converges. Stage II. Diffusion limited aggregation of atomic Au clusters: The solvent has mostly evaporated; however, the nanoclusters may aggregate via thermal diffusion on the surface. The continued application of heat and the lowered dimensionality may facilitate such processes. The nucleation sites have already been created in the previous stage, aligned on a Bénard cell lattice. After baking for 6 minutes, the hexagonal lattice is clearly defined, but the nanostructures are still premature. Stage III. Further aggregation and lateral growth: After baking for 6 minutes, the nanostructures are well separated from each other and formation of the ordered array is completed. This process may be identical with respect to formation of the ordered arrays of cubes and wires.

### SYNTHETIC AND SPECTROSCOPIC EXAMPLES

General

All chemicals were purchased from Aldrich and used as received, including gold(III) chloride (99.9+%), didodecyldimethylammonium bromide (98%), toluene (anhydrous, 99.8%), sodium borohydride (99%), octyl ether (99%), and 1 dodecylthiol (98%).

### Example 1

### Synthesis of Gold Nanoclusters

AuCl₃ (30 mg, 0.1 mmol) and dodecyldimethylammonian bromide (DDAB, 90 mg, 0.2 mmol) were mixed with 10 ml anhydrous toluene under inert gas (e.g. N₂) in a 25 ml tri-neck flask. The solution was sonicated for ˜15 minutes in order to dissolve the AuCl₃. The reaction system was purged with dry nitrogen for ˜30 minutes while stirring. Next a solution of aqueous NaBH₄ (40 μL, 9.0 M, freshly prepared) was injected into the solution of AuCl₃, while stirring vigorously. After stirring this mixture for ˜15 minutes, 1-dodecanethiol (0.8 ml) was added in a dropwise fashion via syringe, to produce a gold colloid. The gold colloid was precipitated from this solution by adding 20 ml of ethanol and allowing the solution to stand for ˜30 minutes to provide gold nanoparticles. The mixture was centrifuged and the supernatant was discarded.

The precipitated gold colloid (gold nanoparticles) was redispersed in a solution of dodecanethiol (2.0 ml) and octyl ether (20 ml). Next, an aliquot (˜5.5 ml) of the mixture was transferred to a 25 ml three-necked flask, which was then purged with N₂ for 15 minutes. The mixture was subsequently refluxed (i.e., heated at approximately 300° C.) for ˜50 minutes while vigorously stirring, providing a solution of gold nanoclusters. As described previously, analysis of the gold nanoclusters was performed using UV-Vis spectroscopy, ESI-MS and matrix assisted laser desorption/ionization (MALDI) mass spectroscopy.

### Example 2

### Synthesis of an Ordered Array of Au Spheres

A solution of Au nanoclusters, as prepared in Example 1, was diluted with toluene to form a 1:2 toluene-diluted solution, and a portion (1 μl) was deposited on a substrate, in this case a carbon transmission electron microscopy (TEM) grid. The TEM grid was baked in ambient air (˜20° C.) on a TEM grid at 95° C. for 6 minutes, to provide the ordered array of Au spheres (size: 5.7±0.2 nm; lattice constant: 9.0±0.1 nm). See FIG. 4.

### Example 3

### Synthesis of an Ordered Array of Au Cubes

A solution of Au nanoclusters, as prepared in Example 1, was diluted with toluene to form a 1:2 toluene-diluted solution, and a portion (1 μl) was deposited on a substrate, in this case a carbon transmission electron microscopy (TEM) grid. The TEM grid was baked in ambient air (˜20° C.) on a TEM grid at 105° C. for 6 minutes, to provide the ordered array of Au cubes (size: 10.4±0.6 nm; lattice constant: 11.4±0.2 nm). See FIG. 5A and FIG. 5B.

### Example 4

### Synthesis of an Ordered Array of Wires

A solution of Au nanoclusters, as prepared in Example 1, was diluted with toluene to form a 1:2 toluene-diluted solution, and a portion (1 μl) was deposited on a substrate, in this case a carbon transmission electron microscopy (TEM) grid. The TEM grid was baked in ambient air (˜20° C.) on a TEM grid at 100° C. for 6 minutes, to provide the ordered array of Au wires (width: 3 nm; length ˜1 μm), coexisting with ordered arrays of spheres in some areas. See FIG. 6.

### Example 5

### Synthesis of Au Nanoclusters Using Octanethiol Ligand

AuCl₃ (30 mg, 0.1 mmol) and dodecyldimethylammonian bromide (DDAB, 90 mg, 0.2 mmol) were mixed with 10 ml anhydrous toluene under inert gas (e.g. N₂) in a 25 ml tri-neck flask. The solution was sonicated for ˜15 minutes in order to dissolve the AuCl₃. The reaction system was purged with dry nitrogen for ˜30 minutes while stirring. Next a solution of aqueous NaBH₄ (40 μL, 9.0 M, freshly prepared) was injected into the solution of AuCl₃, while stirring vigorously. After stirring this mixture for ˜15 minutes, 1-dodecanethiol (0.8 ml) was added in a dropwise fashion via syringe, to produce a gold colloid. The gold colloid was precipitated from this solution by adding 20 ml of ethanol and allowing the solution to stand for ˜30 minutes to provide gold nanoparticles. The mixture was centrifuged and the supernatant was discarded.

The precipitated gold colloid (gold nanoparticles) was redispersed in a solution of dodecanethiol (2 ml) and octyl ether (20 ml). Next, an aliquot (˜5.5 ml) of the mixture was transferred to a 25 ml three-necked flask, which was then purged with N₂ for 15 minutes. The mixture was subsequently refluxed (i.e., heated at approximately 300° C.) for ˜50 minutes while vigorously stirring, providing a solution of gold nanoclusters.

### Example 6

### Synthesis of an Ordered Array of Au Spheres, wherein the Au Spheres were Created Using Au Nanoclusters and Octanethiol Ligand

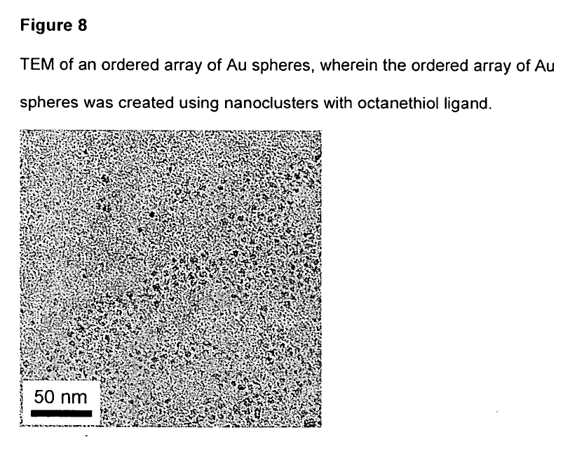

A solution of Au nanoclusters, as prepared in Example 5, was diluted with toluene to form a 1:2 toluene-diluted solution, and a portion (1 μl) was deposited on a substrate, in this case a carbon transmission electron microscopy (TEM) grid. The TEM grid was baked in ambient air (˜20° C.) on a TEM grid at 95° C. for 6 minutes, to provide the ordered array of Au spheres (Lattice constant 8.5±0.7 nm). See FIG. 8.

### Example 7

### Synthesis of an Ordered Array of Au Cubes, wherein the Au Cubes were Created Using Au Nanoclusters and Octanethiol Ligand

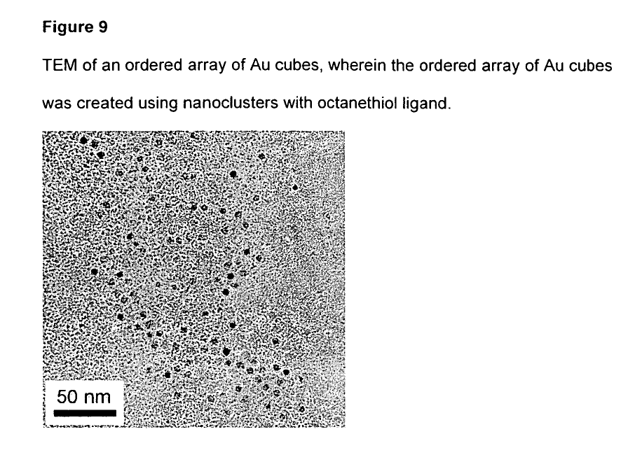

A solution of Au nanoclusters, as prepared in Example 5, was diluted with toluene to form a 1:2 toluene-diluted solution, and a portion (1 μl) was deposited on a substrate, in this case a carbon transmission electron microscopy (TEM) grid. The TEM grid was baked in ambient air (˜20° C.) on a TEM grid at 105° C. for 6 minutes, to provide the ordered array of Au cubes (Lattice constant 10.3±0.6 nm). See FIG. 9.

### Example 8

### Synthesis of Ag Nanoclusters with Dodecanethiol Ligand

AgNO₃ (99+%, 17 mg, 0.1 mmol) and DDAB (90 mg, 0.2 mmol) are mixed with 10 ml anhydrous toluene in a 25 ml tri-neck flask. The reaction system is purged with dry nitrogen for 30 minutes under stirring, while the temperature is kept at 40° C. to dissolve AgNO₃. Aqueous NaBH₄ solution (20 μl, 9.0 M, freshly prepared at 0° C.) is injected via syringe into the solution under vigorous stirring. Within 1 minute, the solution turned yellowish brown. After 30 minutes, the reaction is stopped and the solution is divided into four aliquots and transferred into vials. Next, 1-dodecanethiol (0.2 ml) is added in a dropwise fashion via a syringe to one of the aliquots to provide Ag nanoparticles and dodecanethiol ligand. These Ag nanoparticles are polydispersed, typically ranging from 2 to 15 nm.

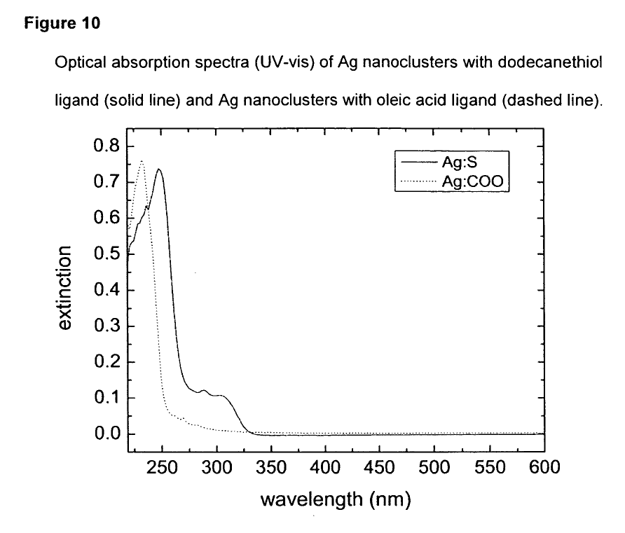

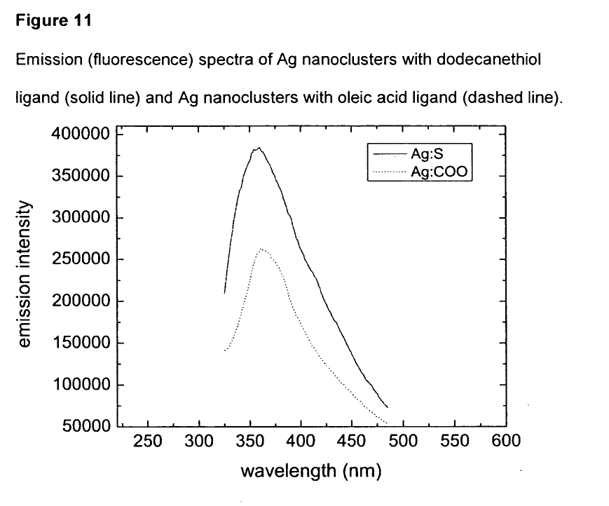

The Ag nanoparticles (0.025 mmol Ag) and dodecanethiol are refluxed in 5 ml dioctyl ether with 0.5 ml of dodecanethiol for ˜1 hour, while the color of the solution changed from yellow brown to faint yellow to provide Ag nanoclusters with dodecanethiol ligand. Without wishing to be bound by any theory of interpretation, it is believed that the high absorption in the UV region of FIGS. 10 and 11 are suggestive of a nanocluster falling within the range of 1 to 7 Ag atoms.

### Example 9

### Synthesis of Ag Nanoclusters with Oleic Acid Ligand

Silver trifluoroacetate (AgO₂CF₃C, 99.99+%, 22 mg, 0.1 mmol), oleic acid (99+%, 0.2 ml), and isoamyl ether (99%, 3 ml) are mixed in a 25 ml tri-neck flask. The reaction system is purged with dry nitrogen for 30 minutes under stirring, then the temperature is gradually raised to 160° C. over 90 minutes. The color of the solution changes from clear to yellowish brown during this period of time. The resulting Ag nanoparticles are narrowly dispersed, with the diameter of 5.2±0.4 nm. See Lin, Xue Zhang et al., Langmuir 2003, 19, 10081-10085.

The Ag nanoparticles (0.025 mmol Ag) and oleic acid are refluxed in 5 ml dioctyl ether with 0.5 ml of oleic acid for ˜1 hour, while the color of the solution changed from yellow brown to faint yellow. Without wishing to be bound by any theory of interpretation, it is believed that the high absorption in the UV region of FIGS. 10 and 11 are suggestive of a nanocluster falling within the range of 1 to 7 Ag atoms.

### Example 10

### Synthesis of an Ordered Array of Ag Spheres, wherein the Ag Spheres were Created Using Ag Nanoclusters and Oleic Acid Ligand

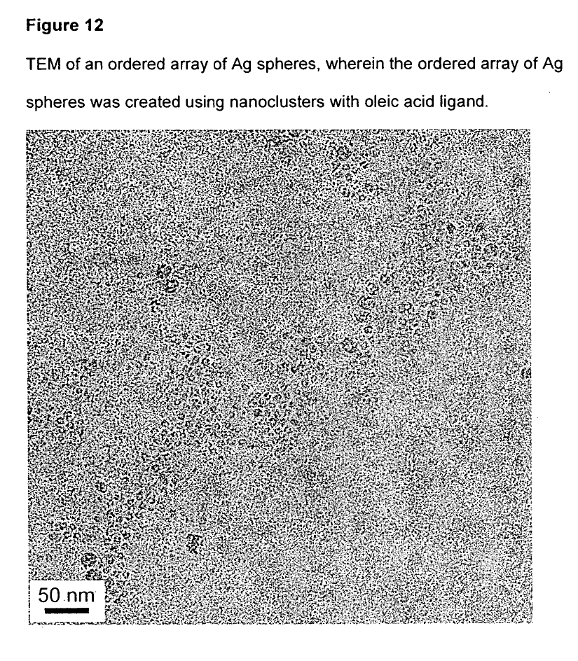

An octyl ether-solution of oleic-acid passivated Ag nanoclusters is diluted with toluene with 1:2 volume ratio, and 1 μl of the mixed solution is deposited on a TEM grid and heated on a hotplate at 95° C. for 6 minutes. A ordered array of Ag spheres was obtained, having a lattice constant of 10.9±0.6 nm and nanoparticle size 6.7±1.1 nm. See FIG. 12.

### Example 11

### Synthesis of Au Nanocluster Solutions at 290° C. and 270° C.

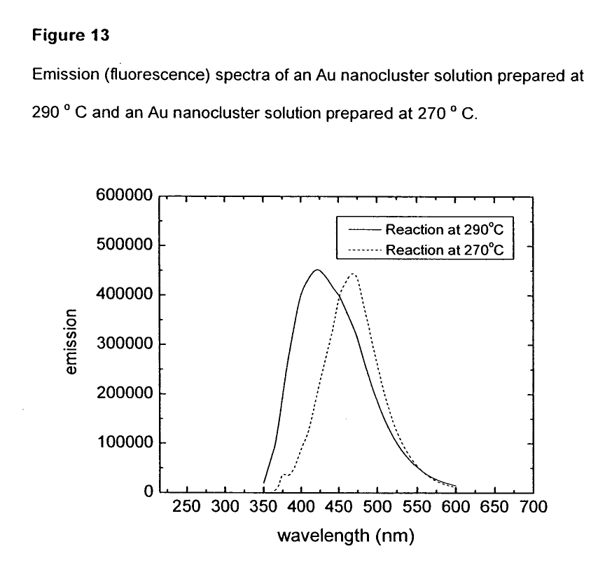

The Au nanocluster solutions of FIG. 13 were prepared as described in Example 1 above. However, to achieve a reaction temperature of 270° C., the mixture of precipitated gold colloid (gold nanoparticles), dodecanethiol (0.4 M) and octyl ether was heated at 270° C., but was not refluxed.

It is therefore intended that the foregoing detailed description be regarded as illustrative rather than limiting, and that it be understood that it is the following claims, including all equivalents, that are intended to define the spirit and scope of this invention.

1. A method of making an ordered array of nanostructures, comprising:
forming a solution of nanoclusters in a high boiling solvent;
depositing the solution on a substrate; and
heating the substrate.

2. The method of claim 1, where the forming the solution of nanoclusters comprises diluting the high boiling solvent with a second solvent.

3. The method of claim 1, where the nanostructures comprise cubes.

4. The ordered array of claim 3, where the cubes have a variability of less than 20%.

5. The method of claim 3, where the cubes have a lattice constant ranging form about 1 nm to about 20 nm.

6. The method of claim 3, where the cubes range in size from about 5 nm to about 20 nm.

7. The method of claim 3, where the nanoclusters comprise gold, and the heating the substrate occurs at about 105° C.

8. The method of claim 1, where the nanostructures comprise spheres.

9. The ordered array of claim 8, where the spheres have a variability of less than 20%.

10. The method of claim 8, where the spheres have a lattice constant ranging form about 1 nm to about 20 nm.

11. The method of claim 8, where the spheres range in size from about 1 nm to about 20 nm.

12. The method of claim 8, where the nanoclusters comprise gold, and the heating the substrate occurs at about 95° C.

13. The method of claim 1, where the nanostructures comprise wires.

14. The method of claim 13, where the wires have a width ranging from about 1 nm to about 10 nm.

15. The method of claim 13, where the nanoclusters comprise Au, and the heating the substrate occurs at about 100° C.

16. The method of claim 1, where the geometry of the nanostructures can be controlled by the temperature at which the heating the substrate is performed.

17. The method of claim 13, where the nanoclusters comprise metal atoms selected from the group consisting of Au, Ag, Fe, Co, Pt, Cu, Ni, Cd, Zn, Mn, Sn, Pb, V, and Ti.

18. The method of claim 17, where the nanoclusters comprise a mixture of metals.

19. The method of claim 17, where the nanoclusters further comprise non-metal atoms.

20. The method of claim 1, where the nanoclusters comprise metal atoms selected from the groups consisting of Au and Ag.

21. The method of claim 1, where the nanoclusters comprise Au.

22. The method of claim 1, where the nanostructures have a lattice constant which increases with a fluid layer thickness.
